(19) United States
(12) Patent Application Publication
(10) Pub. No.: US 2015/0380353 A1
(43) Pub. Date: Dec. 31, 2015

(54) METHOD OF FABRICATING AN INTEGRATED CIRCUIT DEVICE, AND AN INTEGRATED CIRCUIT DEVICE THEREFROM

(71) Applicants: Robert BAUER, (US); Philippe DUPUY, (US)

(72) Inventors: ROBERT BAUER, ISMANING (DE); PHILIPPE DUPUY, TOULOUSE (FR)

(73) Assignee: Freescale Semiconductor, Inc., Austin, TX (US)

(21) Appl. No.: 14/766,144

(22) PCT Filed: Feb. 12, 2013
(86) PCT No.: PCT/IB2013/000430

§ 371 Date: Aug. 6, 2015

(51) Int. Cl. H01L 23/525; H01L 23/495; H01L 23/00

(52) U.S. Cl. CPC H01L 23/5256; H01L 24/83; H01L 24/85; H01L 23/49562; H01L 2924/014; H01L 2924/06

(57) ABSTRACT

A method of fabricating an integrated circuit (IC) device includes mounting, via a first surface thereof, at least one semiconductor die on to a surface of an IC device package, mounting, via an interconnect surface thereof, at least one fuse component on to a second surface of the at least one semiconductor die, the second surface of the at least one semiconductor die having at least one terminal of the at least one active component. The at least one fuse component is mounted such that the interconnect surface of the at least one fuse component is thermally coupled to the second surface of the at least one semiconductor die and electrically coupled to the at least one terminal of the at least one active component. The at least one fuse component is electrically coupled to at least one external connection surface of the IC device package such that the at least one fuse component is electrically coupled in series between the at least one terminal of the at least one active component of the at least one semiconductor die and the at least one external connection surface of the IC device package.

### FIELD OF THE INVENTION

This invention relates to a method of fabricating an integrated circuit device, and an integrated circuit device fabricated therefrom.

### BACKGROUND OF THE INVENTION

In the field of surface mounted power semiconductor devices, for example such as power transistors including power MOSFET (metal oxide semiconductor field effect transistor) devices and IGBT (Insulated Gate Bipolar Transistor) devices, power diodes, thyristors, etc., as well as Gallium nitride (GaN) devices, a failure within such a device, for example caused by a structure breakthrough, can result in excessive current flow through a leakage or shorted path, and in particular can cause the device packaging and nearby devices to reach temperatures that may lead to fatal errors such as the device packaging and nearby devices catching fire. Protecting against such fatal errors is of particular interest in safety critical applications such as automotive applications.

To protect against such a fatal error following a failure within a power semiconductor device, it is necessary to either cut the leakage/shorted path through which the excessive current is flowing, or to limit the current flow there through by increasing the path resistance. It is known to use fuse components within the current path in order to provide such protection. A problem with using discrete fuse components (i.e. fuse components that are not integrated within the integrated circuit (IC) packaging of the power semiconductor device) is that they are required to be separately mounted to the surface of the printed circuit board (PCB), or other surface on to which the power device is mounted, thereby increasing the component count, and thus assembly cost and complexity, as well as increasing the required PCB surface area. Integrated fuse components (i.e. fuse components that are integrated within the IC packaging of the power semiconductor device) are therefore highly desirable.

### SUMMARY OF THE INVENTION

The present invention provides a method of fabricating an integrated circuit (IC) device and an IC device fabricated according to said method as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 is illustrates a simplified cross-sectional view of an example of an integrated circuit (IC) device.

FIG. 2 illustrates a simplified cross-sectional view of an example of part of such vertical diffused metal oxide semiconductor structure.

FIGS. 3 and 4 illustrate simplified cross-sectional views of alternative examples of an IC device.

FIG. 5 illustrates a simplified flowchart of an example of a method of fabricating an IC device.

### DETAILED DESCRIPTION OF THE PREFERRED EMBODIMENTS

The present invention will now be described with reference to an example of an integrated circuit (IC) device comprising one or more vertical diffused metal oxide semiconductor (VDMOS) structures mounted within an overmolded lead frame IC package, and a method of fabrication therefor. However, it will be appreciated that the present invention is not limited to the specific examples herein described with reference to the accompanying drawings. For example, the present invention is not limited to IC devices (and methods of fabrication therefor) comprising VDMOS structures, and may equally be applied to IC devices comprising alternative types of active components. In particular, it is contemplated that the present invention may be applied to IC devices comprising any form of power semiconductor devices such as, by way of example, one or more power metal oxide semiconductor field effect transistor devices, one or more insulated gate bipolar transistor devices, one or more power diode devices, one or more thyristor devices, and/or one or more gallium nitride devices. Furthermore, the present invention is not limited to IC devices (and methods of fabrication therefor) of vertically diffused semiconductor structures, and may equally be applied to laterally diffused (planar) semiconductor structures. Additionally, the present invention is not limited to IC devices (and methods of fabrication therefor) comprising overmolded lead frame IC packages, and may equally be applied to IC devices comprising alternative forms of IC packaging, such as cavity packages, hybrid power modules, etc. Furthermore, because the illustrated embodiments of the present invention may for the most part, be implemented using electronic components and circuits known to those skilled in the art, details will not be explained in any greater extent than that considered necessary as illustrated below, for the understanding and appreciation of the underlying concepts of the present invention and in order not to obfuscate or distract from the teachings of the present invention.

According to some examples, there is provided a method of fabricating an integrated circuit (IC) device. The method comprises mounting, via a first surface thereof, at least one semiconductor die on to a surface of an IC device package, mounting, via an interconnect surface thereof, at least one fuse component on to a second surface of the at least one semiconductor die, the second surface of the at least one semiconductor die comprising at least one terminal of the at least one active component, the at least one fuse component being mounted such that the interconnect surface of the at least one fuse component is thermally coupled to the second surface of the at least one semiconductor die and electrically coupled to the at least one terminal of the at least one active component, and electrically coupling the at least one fuse component to at least one external connection surface of the IC device package such that the at least one fuse component is electrically coupled in series between the at least one terminal of the at least one active component of the at least one semiconductor die and the at least one external connection surface of the IC device package.

In this manner, the fuse component is integrated within the IC device package of the IC device to be protected, thereby substantially alleviating the conventional problems of using discrete fuse components that are required to be separately mounted to the surface of, for example, a printed circuit board (PCB), or other surface on to which the IC device is mounted. Furthermore, by mounting the fuse component on to the semiconductor die in series with the current channel there through in this manner, such that the fuse component is thermally coupled to the semiconductor die, the fuse component is able to provide protection against thermal overload, as well as providing over current protection.

In some examples, the method may comprise mounting the at least one fuse component on to the second surface of the at least one semiconductor die such that the at least one terminal of the at least one active component is electrically and thermally coupled to the interconnect surface of the at least one fuse component over an enlarged area of contact.

In some examples, the method may comprise mounting the at least one fuse component on to the second surface of the at least one semiconductor die such that the at least one terminal of the at least one active component is electrically and thermally coupled to the interconnect surface of the at least one fuse component such that the area of contact comprises at least 50% of a bondable area of the at least one terminal of the at least one active component.

In some examples, mounting the at least one fuse component may comprise applying a fuse attach material to the second surface of the at least one semiconductor die, the fuse attach material being electrically and thermally conductive at least when cured, placing the at least one fuse component on to the second surface of the at least one semiconductor die, and curing the fuse attach material.

In some examples, the fuse attach material may comprise at least one of:
a conductive epoxy; and
solder.

In some examples, the first surface of the at least one semiconductor die may comprise a first current channel terminal of the at least one active component and the second surface of the at least one semiconductor die comprises a second current channel terminal of the at least one active component. Furthermore, the method may comprise mounting the at least one semiconductor die to at least a first external connection surface of the IC device package such that the first current channel terminal of the at least one active component is electrically coupled to the at least first external connection surface of the IC device, mounting the at least one fuse component to the second surface of the at least one semiconductor die such that the second current channel terminal of the at least one active component is electrically and thermally coupled to the interconnect surface of the at least one fuse component, and electrically coupling the at least one fuse component to at least one further external connection surface of the IC device such that the at least one fuse component is electrically coupled in series with the first and second current channel terminals of the at least one active component of the at least one semiconductor die between the first and at least one further external connection surfaces of the IC device.

In some examples, the at least one fuse component may comprise at least one of:
at least one element formed from solder alloy;
at least one micro-mechanical fuse element;
at least one element formed from phase change material; and
at least one resistance wire.

In some examples, the at least one fuse component may further comprise at least one integral connective element arranged to be electrically bonded to the at least one external connection surface of the IC device, and electrically coupling the at least one fuse component to the at least one external connection surface of the IC device package may comprise applying attach material to the at least one external connection surface of the IC device, the attach material being electrically conductive at least when cured, mounting the at least one fuse component on to the second surface of the at least one semiconductor die such that the at least one integral connective element forms a contact with the attach material applied to the at least one external connection surface of the IC device, and curing the attach material applied to the at least one external connection surface of the IC device

In some examples, the at least one integral connective element may be formed from at least one of:
a metal;
a plated metal:
a metal alloy;
a plated metal alloy.

In some examples, the at least one fuse component may be electrically coupled to the at least one external connection surface of the IC device package by way of at least one of:
at least one wire bond;
at least one ribbon bond; and
at least one clip attachment.

In some examples, the at least one fuse component may further comprise at least one bondable surface, and the method may comprises mounting the at least one fuse component such that the at least one bondable surface thereof faces at least partially away from the at least one semiconductor die.

In some examples, the at least one bondable surface may be suitable for establishing a connection using at least one of:
a wire bonding technology;
a solder technology; and
a conductive adhesive material.

In some examples, the at least one bondable surface may be formed from at least one of:
copper;
a copper alloy;
a nickel-iron alloy;
copper with silver plating; and
copper with nickel plating.

In some examples, the at least one external connection surface of the IC device package may comprise at least one of:
a surface of a lead frame of the IC device package arranged to be electrically coupled to at least one external contact of the IC device; and
a surface of a substrate of the IC device package.

In some examples, the at least one active component of the at least one semiconductor die may comprise a power semiconductor device.

In some examples, the at least one active component of the at least one semiconductor die may comprise at least one of:
a power metal oxide semiconductor field effect transistor device;
an insulated gate bipolar transistor device;
a power diode device;
a thyristor device; and
a gallium nitride device.

In some examples, the IC device package may comprise an overmolded, lead frame IC package.

According to a further aspect of the invention, there is provided an integrated circuit (IC) device fabricated according to the aforementioned method. Said IC device comprises at least one semiconductor die comprising at least one active component, and at least one fuse component. The at least one semiconductor die is mounted, via a first surface thereof, to a surface of a package of the IC device. The at least one fuse component is mounted, via an interconnect surface thereof, to a second surface of the at least one semiconductor die, the second surface of the at least one semiconductor die comprising at least one terminal of the at least one active component, the at least one fuse component being mounted such that the interconnect surface of the at least one fuse component is electrically and thermally coupled to the second surface of the at least one active component. The at least one fuse component is electrically coupled to at least one external connection surface of the IC device such that the at least one fuse component is electrically coupled in series between the at least one terminal of the at least one active component of the at least one semiconductor die and the at least one external connection surface of the IC device.

In some examples, the at least one fuse component may be arranged to electrically decouple the at least one terminal of the at least one active component of the at least one semiconductor die from the at least one external connection surface of the IC device upon the at least one fuse component exceeding a temperature threshold.

In some examples, the at least one fuse component may be arranged to electrically decouple the at least one terminal of the at least one active component of the at least one semiconductor die from the at least one external connection surface of the IC device upon a current flow there through exceeding a current threshold.

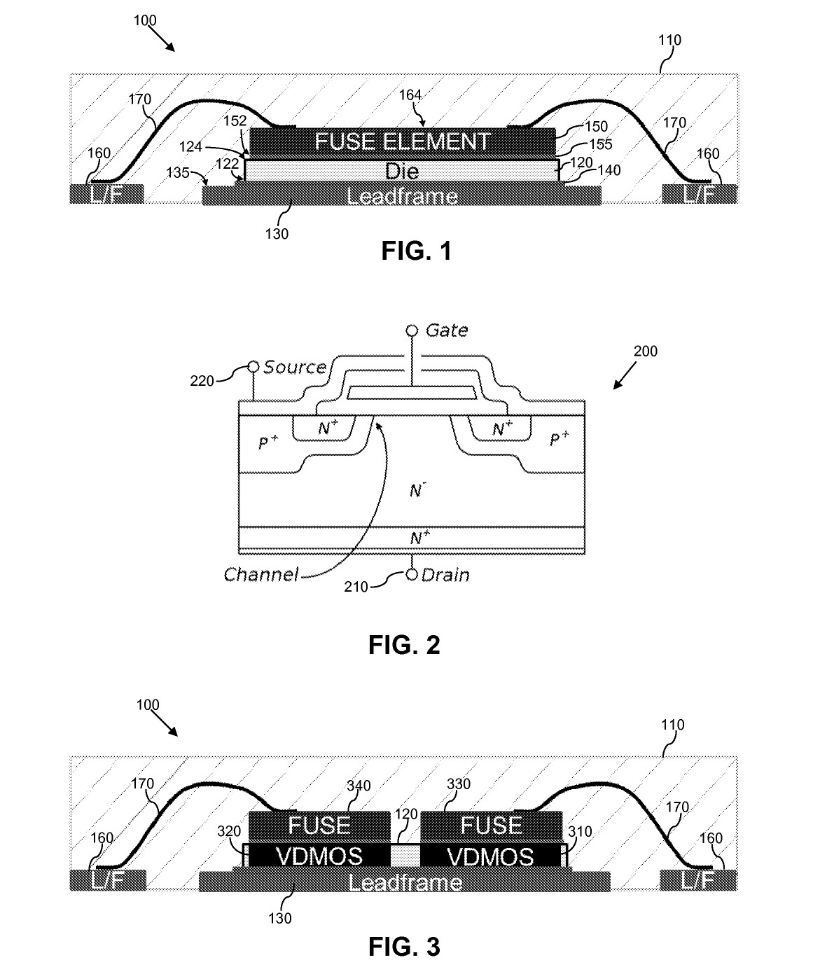

Referring now to FIG. 1, there is illustrated a simplified cross-sectional view of an example of an IC device 100. The IC device 100 comprises an IC package 110 within which at least one semiconductor die 120 is mounted. In the illustrated example, the IC package 110 comprises an overmolded lead frame package, such as a power quad flat-pack no-leads (PQFN) package or small outline IC (SOIC) package. The semiconductor die 120 may comprise one or more active components, and is mounted, via a first surface 122 thereof, on a surface 135 of a substrate 130 of the IC package 110.

FIG. 2 illustrates a simplified cross-sectional view of an example of part of such an active component, which in the illustrated example comprises a VDMOS transistor cell structure 200. VDMOS transistor cell structures, such as illustrated in FIG. 2, are well known in the art, and as such need not be described in any significant detail herein. A drain terminal 210 of the VDMOS transistor structure 200 is located at the ‘bottom’ of the structure, whilst a source terminal 220 of the VDMOS transistor structure 200 is located at the ‘top’ of the structure. In this manner, the current flow channel for the VDMOS transistor structure 200 is orientated substantially vertically (with respect to the semiconductor die plane which is assumed to be orientated substantially horizontally), running between the drain 210 and source 220 current channel terminals of the VDMOS transistor structure 200.

In the example illustrated in FIG. 1, the semiconductor die 120 comprises such a vertically diffused active component, and in particular may comprise a VDMOS transistor made up of a plurality of (e.g. several thousand) cells 200 such as illustrated in FIG. 2. Accordingly, in the example illustrated in FIG. 1, the first surface 122 of the semiconductor die 120 comprises a first current channel terminal of the active component, for example comprising drain terminals 210 of VDMOS cells 200. Furthermore, the substrate 130 of the IC device package 110 comprises a lead frame substrate electrically coupled to one or more external contacts (not shown) of the IC device package 110. In this manner, the semiconductor die 120 is mounted to an external connection surface 135 of the IC device package 110, provided by the lead frame substrate 130, such that the first current channel terminal (e.g. drain terminals 210 of VDMOS cells 200) of the active component within the semiconductor die 120 is electrically coupled to the first external connection surface 135 provided by the lead frame substrate 130.

The semiconductor die 120 may be mounted on to the lead frame substrate 135 in any suitable manner, typically using a die attach material 140. For example, the semiconductor die 120 may be eutectic bonded on to the surface 135 of the lead frame substrate, using a die attach material 140 comprising, say, gold-tin, gold-silicon, tin-silver, tin-silver-copper, tin-lead or tin-lead-silver solder. Alternatively, for low-cost, low-powered applications, the semiconductor die 120 may be attached to the substrate of the IC device package 110 using a die attach material 140 comprising an epoxy or other electrically and thermal conductive adhesive or resin based or synthetic material.

The IC device 100 further comprises a fuse component 150 mounted, via an interconnect surface 152 thereof, on a second surface 124 of the semiconductor die 120. The second surface 124 of the semiconductor die 120 on to which the fuse component 150 is mounted comprises at least one terminal of the active component within the semiconductor die 120. In the example illustrated in FIG. 1, in which the semiconductor die 120 comprises a vertically diffused active component such as a VDMOS transistor, the second surface 124 of the semiconductor die 120 comprises a second current channel terminal of the active component, for example comprising source terminals 220 of the VDMOS cells 200.

In this manner, the fuse component 150 is integrated within the IC device package 110 of the IC device 100 to be protected, thereby substantially alleviating the conventional problems of using discrete fuse components that are required to be separately mounted to the surface of, for example, a printed circuit board (PCB), or other surface on to which the IC device is mounted. Furthermore, by mounting the fuse component 150 on to the semiconductor die 120 such that the fuse component 150 and the semiconductor die 120 are ‘stacked’ one on top of the other, as illustrated in FIG. 1, the coverage area of the IC device 100 is not required to be increased in order to accommodate the fuse component 150.

The fuse component 150 is mounted on to the second surface 124 of the semiconductor die 120 such that the interconnect surface 152 of the fuse component 150 is thermally coupled to the second surface 124 of the semiconductor die 120 and electrically coupled to the terminal of the active component (e.g. the source terminals 220 of VDMOS cells 200). Thus, in the example illustrated in FIG. 1, the fuse component 150 is mounted to the second surface 124 of the semiconductor die 120 such that the second current channel terminal of the active component (e.g. the source terminals 220 of the VDMOS cells 200) is electrically and thermally coupled to the interconnect surface 152 of the fuse component 150.

Significantly, by mounting the fuse component 150 on to the semiconductor die in series with the current channel there through in this manner, such that the fuse component 150 is thermally coupled to the semiconductor die 120, the fuse component 150 is able to provide protection against thermal overload, as well as providing over current protection.

The fuse component 150 is mounted on to the second surface 124 of the semiconductor die 120 such that the terminal of the active component within the second surface 124 of the semiconductor die 120 is electrically and thermally coupled to the interconnect surface 152 of the fuse component 150 over an ‘enlarged area’ of contact. For example, the terminal of the active component within the second surface 124 of the semiconductor die 120 may be electrically and thermally coupled to the interconnect surface 152 of the fuse 150 such that the area of contact comprises at least 50% of the bondable area of the terminal of the active component within the second surface 124 of the semiconductor die 120. For clarity, the bondable area of the terminal of the active component comprises the area which is foreseen to be electrically contacted, and which is typically metallized and not covered by any passivation such as oxide or polyimide layers.

Advantageously, by mounting the fuse component 150 on to the semiconductor die 120 in this manner, such that the semiconductor die 120 is electrically and thermally coupled to the interconnect surface 152 of the fuse component 150 over an ‘enlarged area’ of contact, issues such as intergranular grooving may be reduced or even substantially alleviated. For example, when submitted to repetitive overcurrent stresses, the top metal of a semiconductor die connected with, for example, standard Aluminium bonding sees its resistivity increasing. The aluminium grain and grain size evolve and cracks can appear which create a resistivity increase. The failure mode when totally damaged is a dramatic short circuit. Having an enlarged area of contact on the top metal surface can decrease the local current density, and thus can also decrease the surface strain.

The fuse component 150 may be mounted on to the semiconductor die 120 in any suitable manner, for example by applying a fuse attach material 155 to the second surface 124 of the semiconductor die 120, the fuse attach material 155 being electrically and thermally conductive at least when cured, placing the fuse component 150 on to the second surface 124 of the semiconductor die 120, curing the fuse attach material 155. The fuse attach material 155 may comprise any suitable material, such as a conductive epoxy, solder, etc.

The fuse component 150 is electrically coupled to at least one further external connection surface 160 of the IC device package 100 such that the fuse component 150 is electrically coupled in series between the second surface 124 of the semiconductor die 120 and the external connection surface(s) 160 of the IC device 100. In particular, the fuse component 150 is electrically coupled in series between the active component terminal within the second surface 124 of the semiconductor die 120 (e.g. the source terminals 220 of the VDMOS cells 200) and the external connection surface(s) 160 of the IC device 100. Thus, in the example illustrated in FIG. 1, the fuse component 150 is electrically coupled in series with the current channel of the active component within the semiconductor die 120 between the external connection surfaces 135, 160 of the IC device.

In the example illustrated in FIG. 1, the fuse component 150 may be electrically coupled to the external connection surface(s) 160 of the IC device package 100 in any suitable manner. For example, and as illustrated in FIG. 1, the fuse component 150 may be electrically coupled to the external connection surface(s) 160 of the IC device package 100 by way of one or more conductive bonding elements 170 such as:
one or more wire bonds;
one or more ribbon bonds; and/or
one or more clip attachments.

In some examples, the fuse component 150 may be provided with a bondable surface 164 to facilitate the connection of such bonding elements 170 to the fuse component 150, with the fuse component 150 being mounted such that the bondable surface 164 thereof faces at least partially away from the semiconductor die 120. The bondable surface 164 may be suitable for establishing a connection using one or more of:
a wire bonding technology;
a solder technology; and/or
a conductive adhesive material.

As such, the bondable surface 124 may be formed from one or more of:
copper;
a copper alloy;
a nickel-iron alloy;
copper with silver plating; and/or
copper with nickel plating.

The fuse component 150 may be arranged to electrically decouple second surface 124 of the semiconductor die 120, and thus the terminal of the active component therein, from the external connection surface(s) 160 of the IC device package 100 upon the at least one fuse component exceeding a temperature threshold. Additionally/alternatively, the fuse component 150 may be arranged to electrically decouple second surface 124 of the semiconductor die 120, and thus the terminal of the active component therein, from the external connection surface(s) 160 of the IC device package 100 upon a current flow there through exceeding a current threshold.

Accordingly, the fuse component 150 may comprise one or more of:
at least one element formed from solder alloy;
at least one micro-mechanical fuse element;
at least one element formed from phase change material; and
at least one resistance wire.

FIG. 1 illustrates an example IC device 100 comprising a single channel semiconductor die 120, whereby the semiconductor die 120 comprises a single active component, for example a VDMOS transistor, comprising a single current channel between a first terminal on the first surface 122 of the semiconductor die 120 and a second terminal on the second surface 124 of the semiconductor die 120. It will be appreciated that the present invention may equally be applied to IC devices comprising semiconductor dies comprising more than one current channel.

For example, FIG. 3 illustrates a simplified cross-sectional view of an example of an IC device 100 comprising a semiconductor die 120 mounted on a lead frame 130 within an IC package 110, in a similar manner to the example illustrated in FIG. 1. In the example illustrated in FIG. 3, the semiconductor die 120 comprises two active components in the form of VDMOS transistors 310, 320. In this manner, the semiconductor die 120 in FIG. 3 comprises two current channels, aligned vertically between a first surface 122 of the semiconductor die 120 and a second surface 124 of the semiconductor die 120.

The IC device 100 of FIG. 3 further comprises a first fuse component 330 mounted, via an interconnect surface thereof, on a second surface 124 of the semiconductor die 120 such that the interconnect surface 152 of the first fuse component 330 is thermally coupled to the second surface 124 of the semiconductor die 120 and electrically coupled to a terminal of the first active component 310. The IC device 100 of FIG. 3 further comprises a second fuse component 340 mounted, via an interconnect surface thereof, on the second surface 124 of the semiconductor die 120 such that the interconnect surface of the second fuse component 340 is thermally coupled to the second surface 124 of the semiconductor die 120 and electrically coupled to a terminal of the second active component 320. The first and second fuse components 330, 340 are each electrically coupled to at least one external connection surface 160 of the IC device package 100, for example by way of bonding elements 170. In the illustrated example, the first and second fuse components 330, 340 are illustrated as being located within separate housings. However, it is contemplated that the first and second fuse component 330, 340 may alternatively be located within a single, common housing but without any electrical or thermal coupling there between.

In the examples illustrated in FIGS. 1 and 3, the fuse components 150, 330, 340 are electrically coupled to the external connection surfaces 160 of the respective IC device package 100 by way of bonding elements 170. In some alternative examples, the (or each) fuse component further may comprise at least one integral connective element arranged to be electrically bonded to an external connection surface of the IC device.

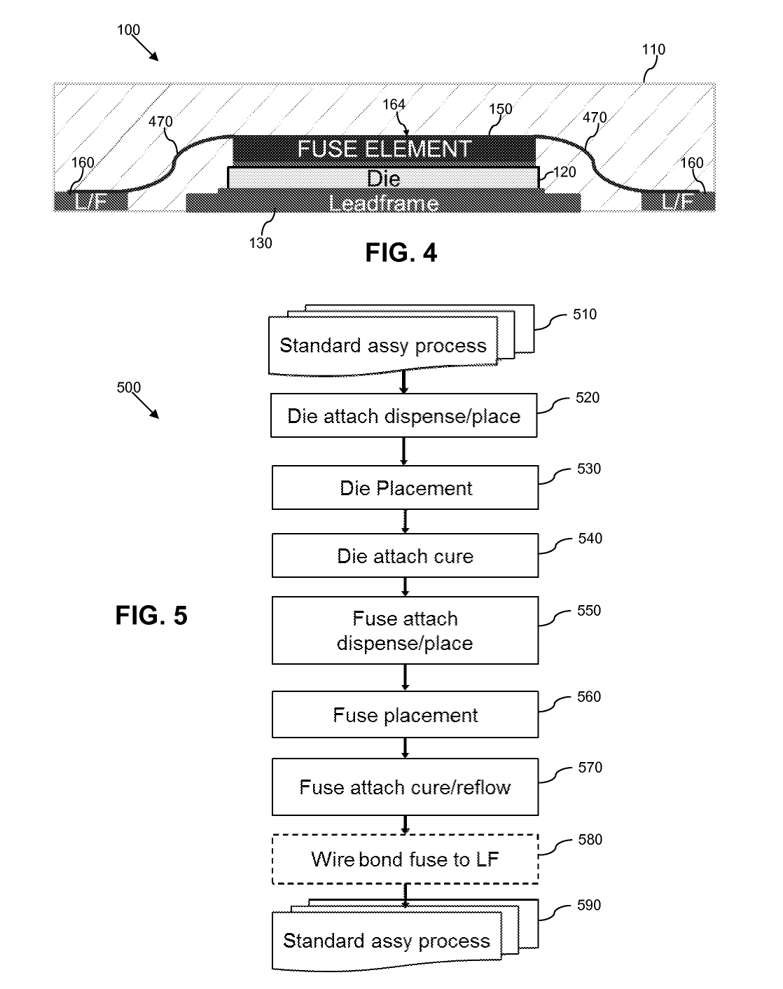

For example, FIG. 4 illustrates a simplified cross-sectional view of an example of an IC device 100 comprising a semiconductor die 120 mounted on a lead frame 130 within an IC package 110 and a fuse component 150 mounted on the semiconductor die 120, in a similar manner to the example illustrated in FIG. 1. In the example illustrated in FIG. 4, the fuse component comprises integral connective elements 470 arranged to be electrically bonded to external connection surfaces 160 of the IC device 100. In the illustrated example, each integral connective element 470 comprises a generally elongate formation extending substantially laterally from or substantially adjacent to an ‘upper’ surface of the fuse component 150 (i.e. a surface facing away from the semiconductor die 120. Each integral connective element 470 is shaped such that, in position, the integral connection element extends out and ‘down’ such that it comes into contact with the respective external connection surface 160, and electrically coupled thereto. For example, an attach material may be applied to the external connection surfaces 160, the attach material being electrically conductive at least when cured. The attach material may comprise the same material as the fuse attach material, such as conductive epoxy, solder, etc. Each integral connective element 470 may be formed from any suitable conductive material, such as a metal or metal alloy. Additionally/alternatively, the integral conductive element 470 may comprise a plated metal or a plated metal alloy. Advantageously, by providing such integral conductive elements 470, no separate assembly step is required to electrically couple the fuse component 150 to the external connection surfaces 160.

In the illustrated examples, the present invention has been described with reference to IC devices comprising vertically diffused semiconductor structures, and in particular to VDMOS structures. As previously mentioned, it is anticipated that the present invention may equally be applied to laterally diffused (planar) semiconductor structures.

Referring now to FIG. 5, there is illustrated a simplified flowchart 500 of an example of a method of fabricating an integrated circuit device, such as one of the IC devise illustrated in FIGS. 1, 3 and/or 4. The method starts at 510 with one or more standard assembly process steps such as, say, one or more semiconductor die preparation steps etc. The method then moves on to 520, where a die attach material is applied to a surface of a substrate (e.g. lead frame substrate) of the IC package on to which the semiconductor die is to be mounted. The semiconductor die is then placed on the surface (in contact with the die attach material), at 530, and the die attach material is then cured at 540 to bond the semiconductor die thereto.

At least one fuse component is then placed, via an interconnect surface thereof, on to a second surface of the semiconductor die, the second surface of the semiconductor die comprising at least one terminal of at least one active component. The at least one fuse component is mounted such that the interconnect surface of the at least one fuse component is thermally coupled to the second surface of the at least one semiconductor die and electrically coupled to the at least one terminal of the at least one active component. In the example illustrated in FIG. 5, the (or each) fuse component is mounted by applying a fuse attach material to the second surface off the semiconductor die, at 550, the fuse attach material being electrically and thermally conductive (at least when cured), placing the at least one fuse component on to the semiconductor die (in contact with the fuse attach material), at 560, and curing the fuse attach material at 570 to bond the fuse component to the second surface of the semiconductor die.

The (or each) fuse component is further electrically coupled to at least one external connection surface of the IC device package such that the fuse component is electrically coupled in series between the terminal(s) of the active component and the external connection surface(s) of the IC device package. In some examples, the (or each) fuse component may be electrically coupled to the external connection surface(s) of the IC device package by way of one or more bonding wires, ribbon bonds and/or clip attachments, such as illustrated in FIGS. 1 and 3. Accordingly, and as illustrated at 580 in FIG. 5, the method may comprise placement and bonding of such wires/ribbons/clip attachments between the (at least one) fuse component and the external surface(s) of the IC device package. Alternatively, in some examples the (or each) fuse component may comprise at least one integral connective element arranged to be electrically bonded to the external connection surface(s) of the IC device package. Accordingly, electrically coupling the fuse component(s) to the external surface(s) of the IC device package may comprise applying attach material to the external connection surface at 550 in FIG. 5, and curing the attach material at 570. In this manner, electrically coupling the fuse component(s) to the external connection surface(s) may be performed at the same time, and by way of substantially the same process as, mounting the fuse component(s) to the semiconductor die. As such, no separate assembly/fabrication step is required for electrically coupling the fuse component(s) to the external connection surface.

The method may then continue with subsequent standard assembly process steps at 590, such any additional wire bonding steps that may be required, etc. before ending.

In the foregoing specification, the invention has been described with reference to specific examples of embodiments of the invention. It will, however, be evident that various modifications and changes may be made therein without departing from the broader spirit and scope of the invention as set forth in the appended claims.

For example, the semiconductor substrate described herein can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A method of fabricating an integrated circuit (IC) device, the method comprising:
mounting, via a first surface thereof, at least one semiconductor die on to a surface of an IC device package;
mounting, via an interconnect surface thereof, at least one fuse component on to a second surface of the at least one semiconductor die, the second surface of the at least one semiconductor die comprising at least one terminal of the at least one active component, the at least one fuse component being mounted such that the interconnect surface of the at least one fuse component is thermally coupled to the second surface of the at least one semiconductor die and electrically coupled to the at least one terminal of the at least one active component; and
electrically coupling the at least one fuse component to at least one external connection surface of the IC device package such that the at least one fuse component is electrically coupled in series between the at least one terminal of the at least one active component of the at least one semiconductor die and the at least one external connection surface of the IC device package.

2. The method of claim 1, wherein the method comprises mounting the at least one fuse component on to the second surface of the at least one semiconductor die such that the at least one terminal of the at least one active component is electrically and thermally coupled to the interconnect surface of the at least one fuse component over an enlarged area of contact.

3. The method of claim 2, wherein the method comprises mounting the at least one fuse component on to the second surface of the at least one semiconductor die such that the at least one terminal of the at least one active component is electrically and thermally coupled to the interconnect surface of the at least one fuse component such that the area of contact comprises at least 50% of a bondable area of the at least one terminal of the at least one active component.

4. The method of claim 2, wherein mounting the at least one fuse component comprises:
applying a fuse attach material to the second surface of the at least one semiconductor die, the fuse attach material being electrically and thermally conductive at least when cured;
placing the at least one fuse component on to the second surface of the at least one semiconductor die; and
curing the fuse attach material.

5. The method of claim 4, wherein the fuse attach material comprises at least one of:
a conductive epoxy; and
solder.

6. The method of claim 1, wherein the first surface of the at least one semiconductor die comprises a first current channel terminal of the at least one active component and the second surface of the at least one semiconductor die comprises a second current channel terminal of the at least one active component, and the method comprises:
mounting the at least one semiconductor die to at least a first external connection surface of the IC device package such that the first current channel terminal of the at least one active component is electrically coupled to the at least first external connection surface of the IC device;
mounting the at least one fuse component to the second surface of the at least one semiconductor die such that the second current channel terminal of the at least one active component is electrically and thermally coupled to the interconnect surface of the at least one fuse component; and
electrically coupling the at least one fuse component to at least one further external connection surface of the IC device such that the at least one fuse component is electrically coupled in series with the first and second current channel terminals of the at least one active component of the at least one semiconductor die between the first and at least one further external connection surfaces of the IC device.

7. The method of claim 1, wherein the at least one fuse component comprises at least one of:
at least one element formed from solder alloy;
at least one micro-mechanical fuse element;
at least one element formed from phase change material; and
at least one resistance wire.

8. The method of claim 1, wherein the at least one fuse component further comprises at least one integral connective element arranged to be electrically bonded to the at least one external connection surface of the IC device, and electrically coupling the at least one fuse component to the at least one external connection surface of the IC device package comprises:
applying attach material to the at least one external connection surface of the IC device, the attach material being electrically conductive at least when cured;
mounting the at least one fuse component on to the second surface of the at least one semiconductor die such that the at least one integral connective element forms a contact with the attach material applied to the at least one external connection surface of the IC device; and
curing the attach material applied to the at least one external connection surface of the IC device

9. The method of claim 8, wherein the at least one integral connective element is formed from at least one of:
a metal;
a plated metal:
a metal alloy;
a plated metal alloy.

10. The method of claim 1, wherein the at least one fuse component is electrically coupled to the at least one external connection surface of the IC device package by way of at least one of:
at least one wire bond;
at least one ribbon bond; and
at least one clip attachment.

11. The method of claim 10, wherein the at least one fuse component further comprises at least one bondable surface, and the method comprises mounting the at least one fuse component such that the at least one bondable surface thereof faces at least partially away from the at least one semiconductor die.

12. The method off claim 11, wherein the at least one bondable surface is suitable for establishing a connection using at least one of:
a wire bonding technology;
a solder technology; and
a conductive adhesive material.

13. The method of claim 12, wherein the at least one bondable surface is formed from at least one of:
copper;
a copper alloy;
a nickel-iron alloy;
copper with silver plating; and
copper with nickel plating.

14. The method of claim 1, wherein the at least one external connection surface of the IC device package comprises at least one of:
a surface of a lead frame of the IC device package arranged to be electrically coupled to at least one external contact of the IC device; and
a surface of a substrate of the IC device package.

15. The method of claim 1, wherein the at least one active component of the at least one semiconductor die comprises a power semiconductor device.

16. The method of claim 15, wherein the at least one active component of the at least one semiconductor die comprises at least one of:
a power metal oxide semiconductor field effect transistor device;
an insulated gate bipolar transistor device;
a power diode device;
a thyristor device; and
a gallium nitride device.

17. The method of claim 1, wherein the IC device package comprises an overmolded, lead frame IC package.

18. An integrated circuit (IC) device comprising:
at least one semiconductor die comprising at least one active component; and
at least one fuse component;
wherein:
the at least one semiconductor die is mounted, via a first surface thereof, to a surface of a package of the IC device;
the at least one fuse component is mounted, via an interconnect surface thereof, to a second surface of the at least one semiconductor die, the second surface of the at least one semiconductor die comprising at least one terminal of the at least one active component, the at least one fuse component being mounted such that the interconnect surface of the at least one fuse component is electrically and thermally coupled to the second surface of the at least one active component; and
the at least one fuse component is electrically coupled to at least one external connection surface of the IC device such that the at least one fuse component is electrically coupled in series between the at least one terminal of the at least one active component of the at least one semiconductor die and the at least one external connection surface of the IC device.

19. The IC device of claim 18, wherein the at least one fuse component is arranged to electrically decouple the at least one terminal of the at least one active component of the at least one semiconductor die from the at least one external connection surface of the IC device upon the at least one fuse component exceeding a temperature threshold.

20. The IC device of claim 18, wherein the at least one fuse component is arranged to electrically decouple the at least one terminal of the at least one active component of the at least one semiconductor die from the at least one external connection surface of the IC device upon a current flow there through exceeding a current threshold.
